(19) United States
(12) Patent Application Publication
(10) Pub. No.: US 2023/0216269 A1
(43) Pub. Date: Jul. 6, 2023

(54) WAFER LEVEL OPTICS FOR STRUCTURED LIGHT GENERATION

(71) Applicant: Meta Platforms Technologies, LLC, Menlo Park, CA (US)

(72) Inventors: Nitay Romano, Nitzan (IL); Yaakov Yonatan Layosh, Ganei Modi'in (IL); Jonatan Ginzburg, San Jose, CA (US)

(21) Appl. No.: 18/085,089

(22) Filed: Dec. 20, 2022

Related U.S. Application Data
(60) Provisional application No. 63/296,214, filed on Jan. 4, 2022.

(51) Int. Cl. H01S 5/02255; H01S 5/42; G01B 11/22

(52) U.S. Cl. CPC H01S 5/02255; H01S 5/423; G01B 11/22

(57) ABSTRACT

Embodiments of the present disclosure relate to a projector that is structured to be incorporated into a small form factor electronic device. In some embodiments, the projector is integrated in a depth camera assembly used for eye tracking and/or determining depth of objects in a local area. The projector includes a vertical cavity surface emitting laser (VCSEL) array and a substrate coupled to the VCSEL array. The VCSEL array is a bottom emitting VCSEL array formed with one or more VCSELs. The substrate includes a plurality of optical features to generate one or more SL patterns from the lights that are emitted from the VCSELs.

### CROSS REFERENCE TO RELATED APPLICATIONS

This application claims the benefit of U.S. Provisional Application No. 63/296,214, filed on Jan. 4, 2022, which is incorporated by reference in its entirety.

### FIELD OF THE INVENTION

This disclosure relates generally to generation of structured light, and more specifically to wafer level optics for structured light generation.

### BACKGROUND

Depth camera systems are increasingly being used in smaller form factor devices (e.g., as part of wearable devices). A depth camera system typically includes a projector and a camera. Accordingly, reducing a form factor of the projector may help reduce the overall form factor of the depth camera system. The projector is used to project a structured light pattern into a local area. However, obtaining target properties of the structured light pattern may require additional optical elements which can prevent conventional depth camera systems from achieving smaller form factors.

### SUMMARY

Embodiments of the present disclosure relate to a projector for generating a SL pattern. The projector may be part of a depth camera assembly (DCA) which can be further incorporated into a small form factor electronic device, for example, a headset, an eyewear device, etc. The projector may be an embodiment of a light source or a projector in a DCA. In some embodiments, the projector may be configured to generate a desirable SL pattern without using a collimator.

In one aspect, the projector presented herein includes a vertical cavity surface emitting laser (VCSEL) array and a substrate coupled to the VCSEL array. The VCSEL is a bottom emitting VCSEL array formed with one or more VCSELs. The substrate includes a plurality of optical features to generate one or more SL patterns from the lights that are emitted from the VCSELs.

In another aspect, this disclosure presents a DCA. The DCA includes a projector and an imaging device. The projector includes a VCSEL array, and a substrate coupled to the VCSEL array. The VCSEL array is a bottom emitting VCSEL array formed with one or more VCSELs. The substrate includes a plurality of optical features to generate one or more SL patterns from the lights that are emitted from the VCSELs. The imaging device may be configured to receive the SL patterns from the projector that is reelected/scattered from the local area.

### BRIEF DESCRIPTION OF THE FIGURES

FIG. 1 is a perspective view of a headset implemented as an eyewear device, in accordance with one or more embodiments.

FIG. 2 is a block diagram of a DCA, in accordance with one or more embodiments.

FIG. 3 is a schematic diagram of a DCA in a local area, in accordance with one or more embodiments.

FIG. 4 shows a cross section of an example projector, in accordance with one or more embodiments.

FIG. 5A shows a cross section of a portion of an example projector that includes a prism, in accordance with one or more embodiments.

FIG. 5B shows an example incoherent irradiance chart for a quasi-sinusoidal pattern, in accordance with one or more embodiments.

FIG. 5C shows a cross section of an example projector including a collimator, in accordance with one or more embodiments.

FIG. 5D shows a cross section of an example projector for flood illumination, in accordance with one or more embodiments.

FIG. 6 is a flowchart illustrating a process for generating a SL pattern, in accordance with one or more embodiments.

FIG. 7 is a system that includes a headset, in accordance with one or more embodiments.

The figures depict embodiments of the present disclosure for purposes of illustration only. One skilled in the art will readily recognize from the following description that alternative embodiments of the structures and methods illustrated herein may be employed without departing from the principles, or benefits touted, of the disclosure described herein.

### DETAILED DESCRIPTION

A depth camera assembly (DCA) determines depth information for a local area. The DCA includes a plurality of cameras and at least one projector. The projector comprises an array of VCSELs. The DCA may select a subset of the VCSELs to provide illumination at any given time.

The projector projects one or more SL patterns into a local area of the DCA. Some or all of the VCSELs of the VCSEL array are bottom emitting VCSELs. A bottom emitting VCSEL emits light from the bottom of a substrate, i.e., the back side of the wafter. The substrate includes an optical layer formed from a portion of the substrate. The optical layer includes a plurality of optical features (e.g., triangle, rectangle, sphere, etc.) to generate one or more SL patterns from the lights that are emitted from the VCSELs. In this way, a wafer level optics is integrated into and/or function as the projector. In some embodiments, the projector does not need a collimator (e.g., as part of a near-field depth determination system) and directly generates SL patterns via the optical layer so that the form factor is much smaller than that of conventional SL projectors.

In some embodiments, the VCSELs are grouped into one or more regions, and each region may be controlled independently. The substrate may include a plurality of wafer level optics (WLO) prisms, and the projector may further include a collimator. The emitted light from the VCSELs in each region passes through the collimator and is projected to a designated region of interest. By switching on the VCSELs from one region to another, the projector may scan a full field of view from one region of interest to another.

In some embodiments, the substrate is a micro lens layer which includes a plurality of micro lenses. The micro lenses are oriented with a certain angle relative their helical axes so that the plurality of micro lenses are wafer level optics that function as a collimator. The light emitted from the VCSEL array may be collimated by the micro lenses and projected as flood light in a local area.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to create content in an artificial reality and/or are otherwise used in an artificial reality. The artificial reality system that provides the artificial reality content may be implemented on various platforms, including a wearable device (e.g., headset) connected to a host computer system, a standalone wearable device (e.g., headset), a mobile device or computing system, or any other hardware platform capable of providing artificial reality content to one or more viewers.

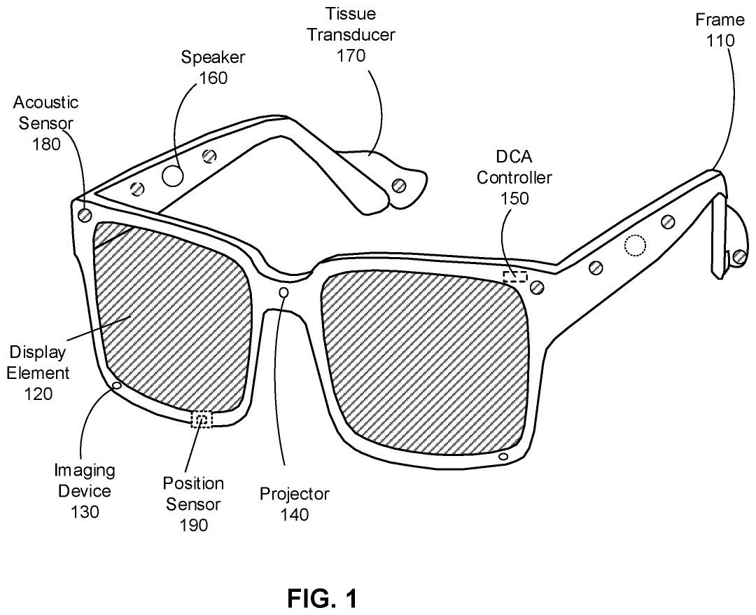

FIG. 1 is a perspective view of a headset 100 implemented as an eyewear device, in accordance with one or more embodiments. In some embodiments, the eyewear device is a near eye display (NED). In general, the headset 100 may be worn on the face of a user such that content (e.g., media content) is presented using a display assembly and/or an audio system. However, the headset 100 may also be used such that media content is presented to a user in a different manner. Examples of media content presented by the headset 100 include one or more images, video, audio, or some combination thereof. The headset 100 includes a frame, and may include, among other components, a display assembly including one or more display elements 120, a depth camera assembly (DCA), an audio system, and a position sensor 190. While FIG. 1 illustrates the components of the headset 100 in example locations on the headset 100, the components may be located elsewhere on the headset 100, on a peripheral device paired with the headset 100, or some combination thereof. Similarly, there may be more or fewer components on the headset 100 than what is shown in FIG. 1.

The frame 110 holds the other components of the headset 100. The frame 110 includes a front part that holds the one or more display elements 120 and end pieces (e.g., temples) to attach to a head of the user. The front part of the frame 110 bridges the top of a nose of the user. The length of the end pieces may be adjustable (e.g., adjustable temple length) to fit different users. The end pieces may also include a portion that curls behind the ear of the user (e.g., temple tip, ear piece).

The one or more display elements 120 provide light to a user wearing the headset 100. As illustrated the headset includes a display element 120 for each eye of a user. In some embodiments, a display element 120 generates image light that is provided to an eyebox of the headset 100. The eyebox is a location in space that an eye of user occupies while wearing the headset 100. For example, a display element 120 may be a waveguide display. A waveguide display includes a light source (e.g., a two-dimensional source, one or more line sources, one or more point sources, etc.) and one or more waveguides. Light from the light source is in-coupled into the one or more waveguides which outputs the light in a manner such that there is pupil replication in an eyebox of the headset 100. In-coupling and/or outcoupling of light from the one or more waveguides may be done using one or more diffraction gratings. In some embodiments, the waveguide display includes a scanning element (e.g., waveguide, mirror, etc.) that scans light from the light source as it is in-coupled into the one or more waveguides. Note that in some embodiments, one or both of the display elements 120 are opaque and do not transmit light from a local area around the headset 100. The local area is the area surrounding the headset 100. For example, the local area may be a room that a user wearing the headset 100 is inside, or the user wearing the headset 100 may be outside and the local area is an outside area. In this context, the headset 100 generates VR content. Alternatively, in some embodiments, one or both of the display elements 120 are at least partially transparent, such that light from the local area may be combined with light from the one or more display elements to produce AR and/or MR content.

In some embodiments, a display element 120 does not generate image light, and instead is a lens that transmits light from the local area to the eyebox. For example, one or both of the display elements 120 may be a lens without correction (non-prescription) or a prescription lens (e.g., single vision, bifocal and trifocal, or progressive) to help correct for defects in a user's eyesight. In some embodiments, the display element 120 may be polarized and/or tinted to protect the user's eyes from the sun.

In some embodiments, the display element 120 may include an additional optics block (not shown). The optics block may include one or more optical elements (e.g., lens, Fresnel lens, etc.) that direct light from the display element 120 to the eyebox. The optics block may, e.g., correct for aberrations in some or all of the image content, magnify some or all of the image, or some combination thereof

The DCA determines depth information for a portion of a local area surrounding the headset 100. The DCA includes one or more imaging devices 130, a DCA controller 150, and a projector 140. In some embodiments, the projector 140 illuminates a portion of the local area with light. The light is structured light (e.g., parallel lines). In some embodiments, the one or more imaging devices 130 capture images of the portion of the local area that include the light from the projector 140. As illustrated, FIG. 1 shows a single projector 140 and two imaging devices 130.

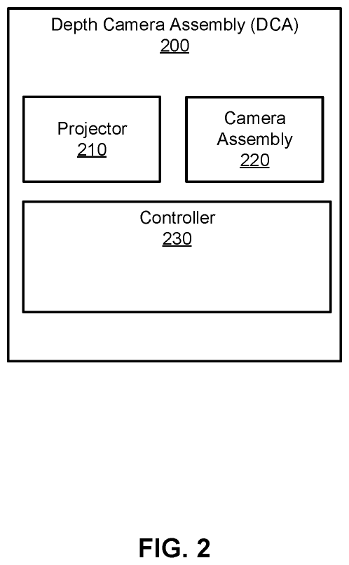

The projector 140 comprises a VCSEL array that includes a substrate. The VCSEL array is a bottom emitting VCSEL array formed with the array of VCSELs. A portion of the substrate is an optical layer that includes a plurality of optical features to generate one or more SL patterns from the lights that are emitted from the VCSELs as further described with respect to FIGS. 2-6. The projector 140 is configured to project one or more SL patterns into to a local area for eye tracking and/or determining depth of objects in the local area. In some embodiments, the optical features are WLO prisms; and in some other embodiments, the substrate is a micro lens layer which includes a plurality of micro lenses.

The projector 140 projects a plurality of SL features, such as lines, that together form the SL pattern. In some embodiments, the SL features from multiple VCSELs combine to form the quasi-sinusoidal SL pattern.

The imaging devices 130 capture images of the local area containing the SL pattern. The DCA controller 150 calculates depth information based on distortions of the SL pattern in the images captured by the imaging devices 130. The DCA controller 150 may determine depth to objects in the local area using an initial depth sensing mode, such as direct (or indirect) time-of flight(ToF), then, based on a calculated depth to the objects, the DCA controller 150 may select VCSELs for activation in the portion of the local area containing the object.

The audio system provides audio content. The audio system includes a transducer array, a sensor array, and an audio controller. However, in other embodiments, the audio system may include different and/or additional components. Similarly, in some cases, functionality described with reference to the components of the audio system can be distributed among the components in a different manner than is described here. For example, some or all of the functions of the controller may be performed by a remote server.

The transducer array presents sound to user. The transducer array includes a plurality of transducers. A transducer may be a speaker 160 or a tissue transducer 170 (e.g., a bone conduction transducer or a cartilage conduction transducer). Although the speakers 160 are shown exterior to the frame 110, the speakers 160 may be enclosed in the frame 110. In some embodiments, instead of individual speakers for each ear, the headset 100 includes a speaker array comprising multiple speakers integrated into the frame 110 to improve directionality of presented audio content. The tissue transducer 170 couples to the head of the user and directly vibrates tissue (e.g., bone or cartilage) of the user to generate sound. The number and/or locations of transducers may be different from what is shown in FIG. 1.

The sensor array detects sounds within the local area of the headset 100. The sensor array includes a plurality of acoustic sensors 180. An acoustic sensor 180 captures sounds emitted from one or more sound sources in the local area (e.g., a room). Each acoustic sensor is configured to detect sound and convert the detected sound into an electronic format (analog or digital). The acoustic sensors 180 may be acoustic wave sensors, microphones, sound transducers, or similar sensors that are suitable for detecting sounds.

In some embodiments, one or more acoustic sensors 180 may be placed in an ear canal of each ear (e.g., acting as binaural microphones). In some embodiments, the acoustic sensors 180 may be placed on an exterior surface of the headset 100, placed on an interior surface of the headset 100, separate from the headset 100 (e.g., part of some other device), or some combination thereof. The number and/or locations of acoustic sensors 180 may be different from what is shown in FIG. 1. For example, the number of acoustic detection locations may be increased to increase the amount of audio information collected and the sensitivity and/or accuracy of the information. The acoustic detection locations may be oriented such that the microphone is able to detect sounds in a wide range of directions surrounding the user wearing the headset 100.

An audio controller processes information from the sensor array that describes sounds detected by the sensor array. The audio controller may comprise a processor and a computer-readable storage medium. The audio controller may be configured to generate direction of arrival (DOA) estimates, generate acoustic transfer functions (e.g., array transfer functions and/or head-related transfer functions), track the location of sound sources, form beams in the direction of sound sources, classify sound sources, generate sound filters for the speakers 160, or some combination thereof.

The position sensor 190 generates one or more measurement signals in response to motion of the headset 100. The position sensor 190 may be located on a portion of the frame 110 of the headset 100. The position sensor 190 may include an inertial measurement unit (IMU). Examples of position sensor 190 include: one or more accelerometers, one or more gyroscopes, one or more magnetometers, another suitable type of sensor that detects motion, a type of sensor used for error correction of the IMU, or some combination thereof. The position sensor 190 may be located external to the IMU, internal to the IMU, or some combination thereof.

In some embodiments, the headset 100 may provide for simultaneous localization and mapping (SLAM) for a position of the headset 100 and updating of a model of the local area. For example, the headset 100 may include a passive camera assembly (PCA) that generates color image data. The PCA may include one or more RGB cameras that capture images of some or all of the local area. In some embodiments, some or all of the imaging devices 130 of the DCA may also function as the PCA. The images captured by the PCA and the depth information determined by the DCA may be used to determine parameters of the local area, generate a model of the local area, update a model of the local area, or some combination thereof. Furthermore, the position sensor 190 tracks the position (e.g., location and pose) of the headset 100 within the room.

FIG. 2 is a block diagram of a DCA 200, in accordance with one or more embodiments. The DCA of FIG. 1 may be an embodiment of the DCA 200. The DCA 200 is configured to obtain depth information of a local area surrounding the DCA 200. For example, the DCA 200 may be configured to detect the location of objects in a room. The DCA may be also used for eye tracking and/or determining depth of objects in a local area. The DCA 200 comprises a projector 210, a camera assembly 220, and a DCA controller 230. Some embodiments of the DCA 200 have different components than those described here. Similarly, in some cases, functions can be distributed among the components in a different manner than is described here.

The projector 140 of FIG. 1 may be an embodiment of the projector 210. The projector 210 may be used for eye tracking and/or determining depth of objects in a local area. As such, the projector 210 may be incorporated in a headset (e.g., an eyewear device 100).

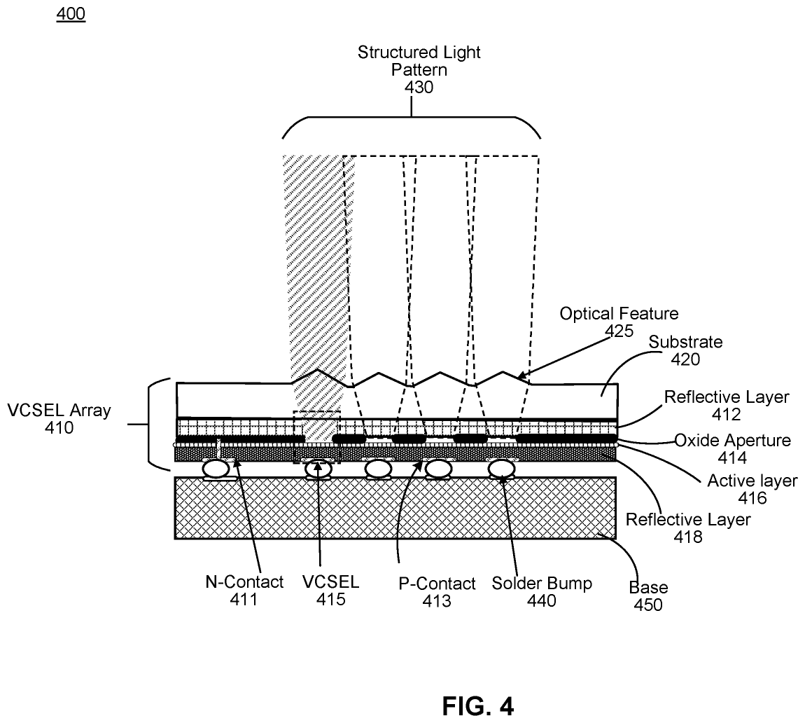

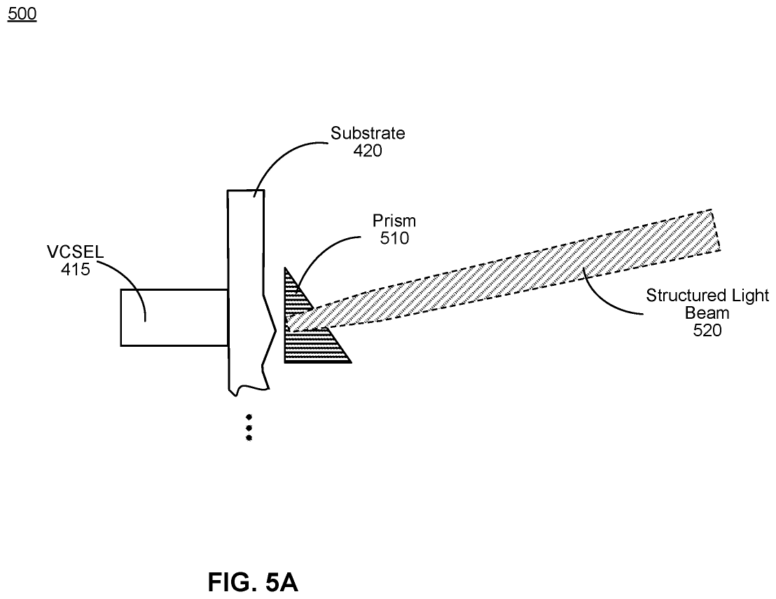

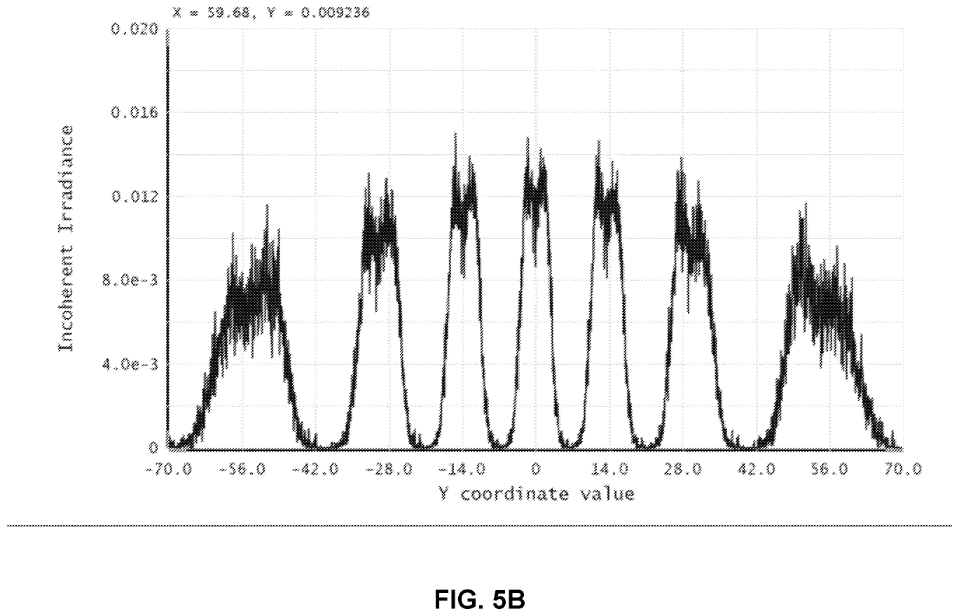

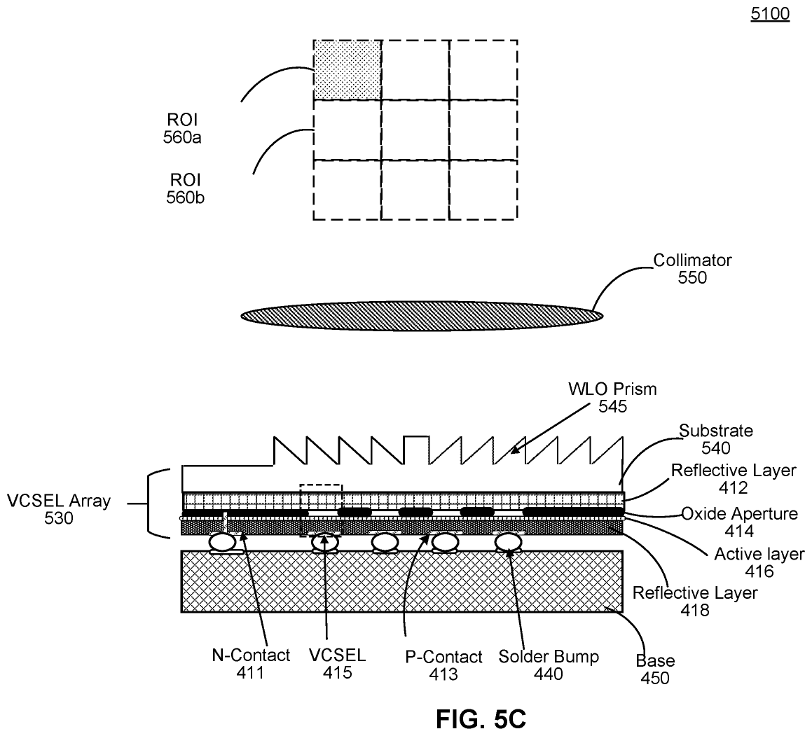

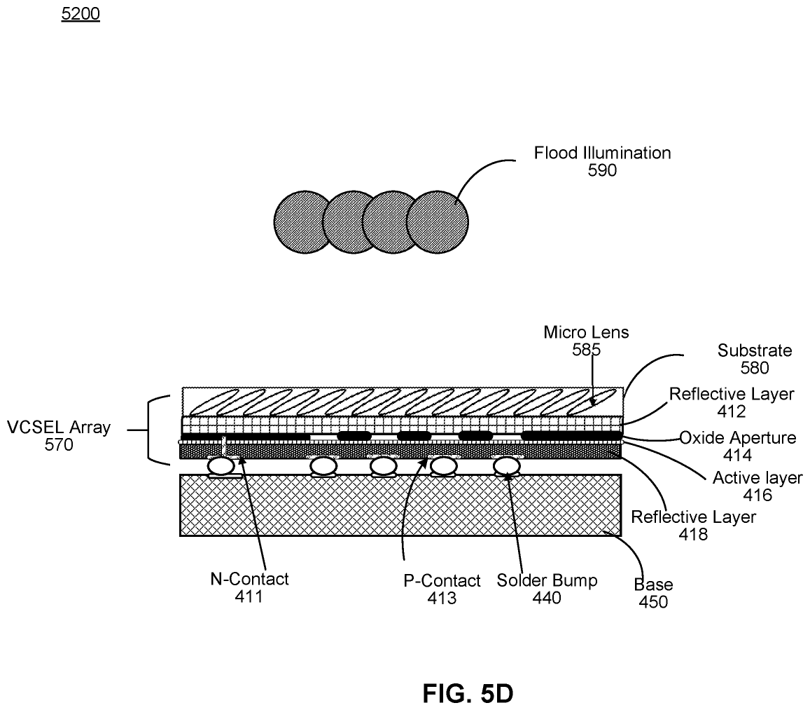

The projector 210 is configured to project light into the local area. The light may include a SL pattern (e.g., lines). The SL pattern may comprise a dot pattern, a bar pattern, a quasi-sinusoidal pattern, some other pattern, or some combination thereof. For example, a SL feature may be a line of a group of parallel lines that make up the SL pattern. In other embodiments, the projected light may be flood illumination. The projected light reflects off objects in the local area, and a portion of the reflected light is detected by the camera assembly 220. The projector 210 comprises a VCSEL array and an optical assembly. The projector 210 can be a projector that includes a VCSEL array with a substrate comprising an optical layer. In some embodiments, the optical layer includes a plurality of optical features which are wafer level optics. The plurality of optical features may generate SL patterns from the emitted light of flood illumination (as described in detail below with regard to FIG. 4 and FIG. 5A-D). The wafer level optics is integrated into and/or function as the projector 210. In some embodiments, the projector 210 does not need a collimator and directly generates SL patterns via the optical layer so that the form factor is much smaller than that of conventional SL projectors. For example, if the DCA 200 is configured for near-field uses (e.g., eye tracking), no collimator may be needed in the projector 210. An example is described below with regard to FIG. 4. In other embodiments, a collimator may be used. For example, if the DCA 200 is configured for far-field uses (e.g., determining depth of a room), the projector 210 may include a collimator to help ensure integrity of a SL pattern over a larger distance.

The VCSEL array is configured to emit light in accordance with instructions from the DCA controller 230. The VCSEL array comprises a plurality of VCSELs on a chip. Some or all of the VCSELs may be individually activated. In some embodiments, the VCSELs are grouped into one or more regions, and each region may be controlled by the DCA controller 230 independently. By switching on the VCSELs from one region to another, the projector may scan a full field of view from one region of interest to another.

The camera assembly 220 is configured to capture light from the local area in accordance with instructions from the DCA controller 230. The imaging devices 130 of FIG. 1 may be embodiments of the camera assembly 220. The camera assembly comprises one or more cameras, and each camera may comprise one or more sensors. In some embodiments, each sensor may comprise a charge-coupled device (CCD) or a complementary metal-oxide-semiconductor (CMOS). Each sensor comprises a plurality of pixels. Each pixel is configured to detect photons incident on the pixel. The pixels are configured to detect a narrow bandwidth of light including the wavelength of the light projected by the projector 210. Each pixel may correspond to a distinct direction relative to the sensor.

The DCA controller 230 is configured to provide instructions to the various components of the DCA 200 and calculate depth information for the local area. The DCA controller 150 of FIG. 1 may be an embodiment of the DCA controller 230. Some embodiments of the DCA controller 230 have different components than those described here. Similarly, in some cases, functions can be distributed among the components in a different manner than is described here.

The DCA controller 230 generates instructions for the projector 210 to project SL patterns into the local area. The DCA controller 230 may instruct the projector 210 to project different SL patterns into different portions of the local area. The SL pattern may comprise a dot pattern, a bar pattern, a quasi-sinusoidal pattern, some other pattern, or some combination thereof. The DCA controller 230 may generate instructions for the projector 210 to project lights into the local area from one designated region of interest to another. Alternatively, the DCA controller 230 may generate instructions for the projector 210 to project flood light into the local area.

The DCA controller 230 is configured to generate instructions for the camera assembly 220 to obtain depth information. The DCA controller 230 is configured to calculate depth information based on the information obtained by the camera assembly 220. The DCA controller 230 may obtain depth measurements using a depth sensing mode. The depth sensing mode may be ToF depth sensing, SL depth sensing, passive stereo depth sensing, active stereo depth sensing, structured stereo depth sensing, or some combination thereof. In some embodiments, the DCA controller 230 obtains depth information without illumination of the local area using a passive stereo depth sensing mode. The DCA controller 230 may store the depth information in a depth model. The depth controller 230 may identify regions of the local area to illuminate based on locations of detected objects in the local area.

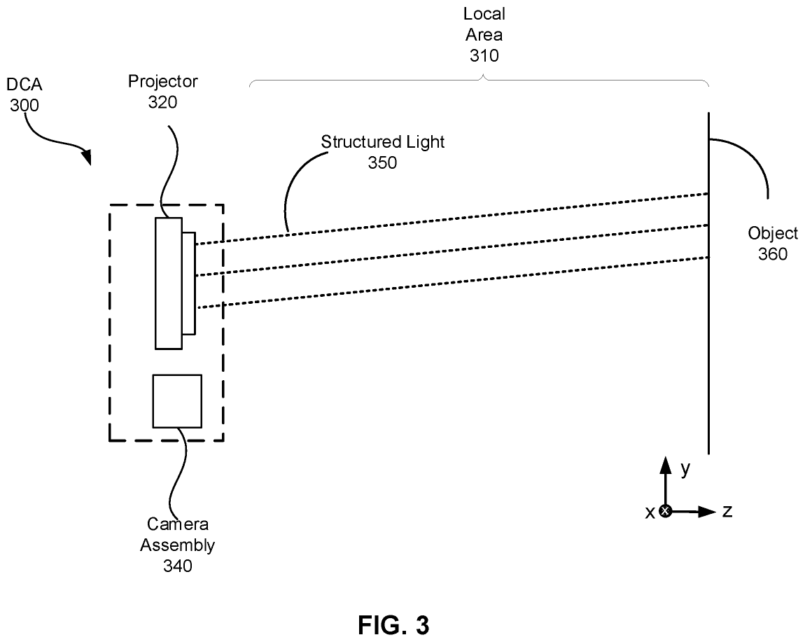

FIG. 3 is a schematic diagram of a DCA 300 obtaining depth information in a local area 310, in accordance with one or more embodiments. The DCA 300 may be an embodiment of the DCA 200 of FIG. 2. The DCA 300 comprises a projector 320. The projector 320 is an embodiment of the projector 210 of FIG. 2. The DCA 300 may project a SL pattern toward an object 360 in a local area 310 of the DCA 300.

FIG. 4 shows a cross section of an example projector 400, in accordance with one or more embodiments. The projector 400 includes a VCSEL array 410, one or more solder bumps 440 and a base 450. The projector 400 may be an embodiment of the projector 210 in the DCA 200. In other embodiments not shown in FIG. 4 the projector 400 may include different and/or additional components.

The VCSEL array 410 is a structured light emitter that is configured to generate one or more SL patterns. The VCSEL array 410 includes one or more bottom emitting VCSELs 415 and a substrate 420. The VCSELs 415 are configured to emit light which pass through the substrate 420 to form one or more SL patterns 430 from the emitted light. In some embodiments, the VCSELs 415 may formed in a one-dimensional or a two-dimensional array.

Each VCSELs 415 includes a reflective layer 412, an oxide aperture layer 414, an active layer 416, and a reflective layer 418. The reflective layer 412 may be an N-type reflector that is formed on the substrate 420. The reflective layer 418 may be a P-type reflector that is electrically coupled to the base 419. The reflective layer 412 and the reflective layer 418 form a diode junction. The active layer 416, positioned between the reflective layer 412 and the reflective layer 418, is configured for the laser light generation. The oxide aperture layer 414 comprises one or more apertures that allow the emitted light to pass through. Additionally, the VCSEL array 410 may further include one or more N-contacts (e.g., N-contact 411) and one or more P-contacts (e.g., P-contact 413) for providing electrical connections.

The substrate 420 is coupled to the VCSEL array 410 and includes a plurality of optical features (e.g., the optical feature 425) to generate one or more SL 430 patterns from the light emitted by the VCSELs (e.g., VCSEL 415). The optical features are used to modify the emitted light. Depending on the size, shape, orientation, etc. of the optical features, the light emitted from the VCSEL array 410, when passing through these optical features, become the SL pattern 430.

In some embodiments, the optical features form a one-dimensional grating on a portion of the surface of the substrate 420. In some embodiments, the optical features may form a two-dimensional grating on the surface of the substrate 420. In some embodiments, the optical features may have geometric shapes, such as, triangle, rectangle, sphere, etc. In some embodiments, each optical feature on the substrate 420 may be identical in shape, size, orientation, etc.; alternatively, the optical features on the substrate 420 may be different in shape, size, orientation, etc.; and in some embodiments, the optical features may form a repeated pattern on the substrate 420. The optical features may be formed in groups, and different groups of the optical features are configured to generate different patterns of SL that are diffracted at different angles. The SL pattern 430 may comprise a dot pattern, a bar pattern, a quasi-sinusoidal pattern, some other pattern, or some combination thereof. As shown in FIG. 4, the optical features are a series of triangular features on the substrate 420. The generated SL pattern 430 may include a quasi-sinusoidal bar pattern.

The substrate 420 is composed of a material that is transparent to the emitted light from the VCSEL array 410. In some embodiments, the substrate 420 may include GaAs. In some embodiments, the projector 400 may include one or more additional optical layers that are stacked on top of the substrate 420. The one or more additional optical layers may each include one or more optical features so that the one or more additional optical layers can further modify the various one or more patterns of the SL that can be emitted from the substrate 420.

The one or more VCSELs 415 are formed on the substrate 420 to form the VCSEL array 410. The one or more VCSELs 415 may be formed layer by layer, e.g., from the reflective layer 412 to the reflective layer 418, on the substrate 420. The substrate 420 may be etched to form the one or more optical features. In some embodiments, one or more layers of substrates 420 may be stacked, and each layer of substrates 420 may be etched to include a set of optical features. Different sets of optical features may be the same or different. The emitted light passes through the layers of substrates 420 to generate one or more SL patterns. The formed VCSEL array 410 is bonded to the base 450 with a plurality of solder bumps 440 to form the projector 400. In some embodiments, the substrate 420 may be etched after the one VCSEL array 410 may be bonded to the base 450. The optical features of the one or more layers of substrate 420 are wafer level optics. In FIG. 4, the wafer level optics facilitate generation of the SL pattern 430 without a collimator—and instead directly generates SL patterns via the optical features (e.g., the optical feature 425).

FIG. 5A shows a cross section of a portion 500 of an example projector that includes a prism 510, in accordance with one or more embodiments. The projector is substantially the same as the projector 400, except that it includes the prism 510. For simplicity, the illustrated portion 500 of the projector includes the VCSEL 415, the substrate 420, a prism 510 for generating SL 520 beam. One or more SL beams form a SL pattern. In a small form factor device, the emitted SL 520 does not have a long distance to pass before it illuminates an object (as shown in FIG. 2). Therefore, the emitted SL 520 beam often does not have a large divergence angle. As such, in some embodiments, the projector may achieve a desired divergence angle without using a collimator.

In some embodiments, the diameter of the SL beam and the distance between the neighboring VCSELs 415 are of similar sizes, so that each SL beam may be treated separately. For example, the diameter of the SL beam 520 may be 48 μm and the distance between the neighboring VCSELs 415 is 40 μm. In this case, the emitted SL beam 520 can be treated separately and different optical elements (e.g., prism 510) can be applied to each emitted SL beam to modify the SL beam independently. The optical elements may include one or more of lens, mirror, prism, etc. As shown in FIG. 5, the prism 510 is coupled to the substrate 420, and the emitted SL 520 is diverged by the prism 510, thus increasing a projected field of view of the SL 520. In some embodiments, one or more prisms may be positioned within an area of the substrate, for example, along a peripheral area of the substrate to change the direction of the SL beams on the edge. This may be used to help, e.g., spread the resulting SL pattern across a larger target area. Alternatively, the prisms may be positioned in any area of the substrate to change the direction of a selected SL beam. In some embodiments, different optical elements may be coupled to the substrate to modify the selected SL beam independently.

FIG. 5B shows an example incoherent irradiance chart for a quasi-sinusoidal pattern, in accordance with one or more embodiments. The projector may be, e.g., the projector 210. The projector projects a plurality of SL features, such as lines, that together form the quasi-sinusoidal pattern.

FIG. 5C shows a cross section of an example projector 5100 including a collimator 550, in accordance with one or more embodiments. The projector 5100 includes a VCSEL array 530, the collimator 550, one or more solder bumps 440 and a base 450. The projector 5100 may be an embodiment of the projector 210 in the DCA 200. In other embodiments not shown in FIG. 5C the projector 5100 may include different and/or additional components.

The VCSEL array 530 is a bottom emitting VCSEL and includes a substrate 540. The VCSEL array 530 is substantially the same as the VCSEL array 410, except that the substrate 540 includes a plurality of wafer level optics (WLO) prisms 545. The substrate 540 is etched to include the plurality of WLO prisms 545 as the optical features that are integrated into and/or function as part of the projector 5100. The WLO prisms 545 may include one or more one or more angles or orientations. In some embodiments, each WLO prism 545 may correspond to one VCSEL 415 to modify the output angle of each emitted light beam independently.

In some embodiments, the VCSELs 415 may formed in a one-dimensional or a two-dimensional VCSEL array 530. For example, the VCSEL array 530 may include one or more rows of VCSELs 415 and each row of VCSELs 415 may include one or more individual VCSELs 415. Additionally, each VCSEL 415 may be controlled by a controller (e.g., the DCA controller 230) independently to switch on and off. Alternatively, a row of VCSELs 415 may be controlled independently by the controller so that one or more rows may be switched on or off at the same time.

The collimator 550 is configured to modify the emitted light from the projector 5100. The collimator 550 collimates the light emitted from the VCSEL array 530 in one or two dimensions. In some embodiments, the collimator 550 may cause the directions of motion to become more aligned in a specific direction, for example, converging the diverging light into a parallel beam. In some embodiments, the collimator 550 may cause the spatial cross section of the light beam to become smaller. The light output from the collimator 550 forms a structured light pattern. As the SL pattern is collimated, the projector 5100 is suitable for use over larger distances (e.g., determining depth in a room) as well as in the near field (e.g., less than 1 meter).

As shown in FIG. 5C, the VCSELs 415 of the projector 5100 may form one or more regions, and the VCSELs 415 in each region may be controlled collectively by a controller. In some embodiments, only one region of the VCSELs 415 is switched on at a time. The emitted light passes through the collimator 550 and is projected to a designated region of interest (ROI), for example, ROI 560a, ROI 560b, etc., (collectively referred to as “ROI 560”). The ROI 560 is a plane parallel to the base 450 and perpendicular to the cross section of the projector 5100. For simplicity, a top view of the ROI 560 is illustrated in FIG. 5C. By switching on the VCSELs 415 from one region to another, the projector 5100 may scan a full field of view from one ROI 560 to another. The number of VCSELs 415 in each region may be adjusted, and more VCSELs 415 in a region may increase the depth resolution of the projector 5100.

FIG. 5D shows a cross section of an example projector 5200 for flood illumination, in accordance with one or more embodiments. The projector 5200 includes a VCSEL array 570, one or more solder bumps 440 and a base 450. The projector 5200 may be an embodiment of the projector 210 in the DCA 200. In other embodiments not shown in FIG. 5D the projector 5200 may include different and/or additional components.

The VCSEL array 570 is a bottom emitting VCSEL and includes a substrate 580. The VCSEL array 570 is substantially the same as the VCSEL array 410, except that the substrate 580 is a micro lens layer which includes a plurality of micro lenses 585 rather than optical features. The plurality of micro lenses 585 are wafer level optics that are integrated into and/or function as part of the projector 5200. In some embodiments, in the substrate 580, the plurality of micro lenses 585 are oriented with a certain angle relative the helical axes of the micro lenses 585. The light emitted from the VCSEL array 570 may be modified by the micro lenses 585 and projected as flood illumination 590, flooding a local area with light. The flood illumination 590 may be used by the DCA to, e.g., determine depth information using a direct ToF or an indirect ToF depth determination technique.

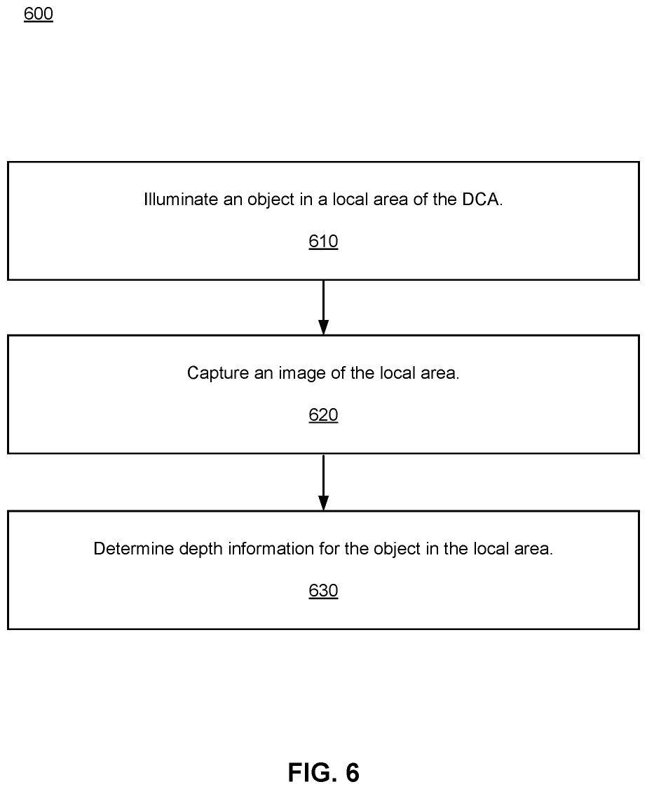

FIG. 6 is a flowchart illustrating a process 600 for generating a SL pattern using a projector, in accordance with one or more embodiments. The process shown in FIG. 6 may be performed by components of a DCA (e.g., DCA 200 of FIG. 2). Other entities may perform some or all of the steps in FIG. 6 in other embodiments. Embodiments may include different and/or additional steps or perform the steps in different orders.

The DCA illuminates 610 an object in a local area of the DCA. The DCA illuminates the object using a projector. The projector includes a substrate that is etched to include one or more optical features. The optical features create a wafer level optics that is integrated into and/or function as the projector. In some embodiments, the projector does not need a collimator and directly generates SL patterns via the optical features. The SL pattern may be, e.g., a dot pattern, a bar pattern, a quasi-sinusoidal pattern, some other pattern, or some combination thereof. In other embodiments, the projected light may be flood illumination.

The DCA captures 620 an image of the local area. The DCA captures the image using a camera assembly. The image includes the projected SL pattern in the local areal.

The DCA determines 630 depth information for the object in the local area. The DCA may apply a depth algorithm (e.g., structured light, direct ToF, indirect ToF) to the image to calculate a depth for each pixel of a sensor of a camera of a depth camera assembly.

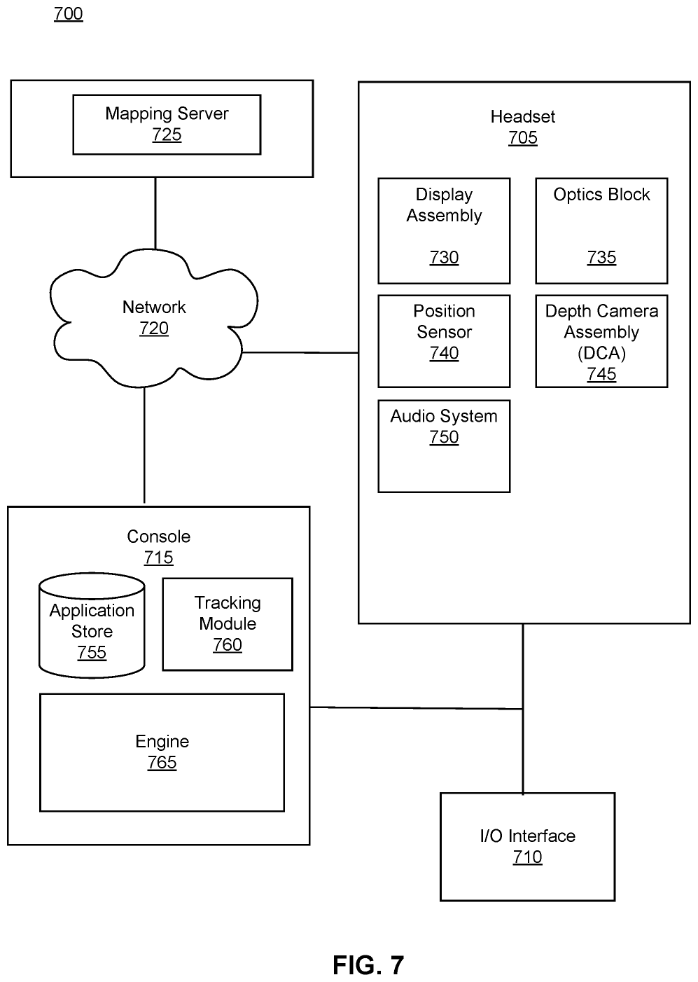

FIG. 7 is a system 700 that includes a headset 705, in accordance with one or more embodiments. In some embodiments, the headset 705 may be the headset 100 of FIG. 1. The system 700 may operate in an artificial reality environment (e.g., a virtual reality environment, an augmented reality environment, a mixed reality environment, or some combination thereof). The system 700 shown by FIG. 7 includes the headset 705, an input/output (I/O) interface 710 that is coupled to a console 715. While FIG. 7 shows an example system 700 including one headset 705 and one I/O interface 710, in other embodiments any number of these components may be included in the system 700. For example, there may be multiple headsets each having an associated I/O interface 710, with each headset and I/O interface 710 communicating with the console 715. In alternative configurations, different and/or additional components may be included in the system 700. Additionally, functionality described in conjunction with one or more of the components shown in FIG. 7 may be distributed among the components in a different manner than described in conjunction with FIG. 7 in some embodiments. For example, some or all of the functionality of the console 715 may be provided by the headset 705.

The headset 705 includes the display assembly 730, an optics block 735, one or more position sensors 740, and the DCA 745. Some embodiments of headset 705 have different components than those described in conjunction with FIG. 7. Additionally, the functionality provided by various components described in conjunction with FIG. 7 may be differently distributed among the components of the headset 705 in other embodiments, or be captured in separate assemblies remote from the headset 705.

The display assembly 730 displays content to the user in accordance with data received from the console 715. The display assembly 730 is an embodiment of the display assembly 200. The display assembly 730 displays the content using one or more display elements (e.g., the display elements 210) that include respective actuator aligned multi-channel projectors and combination elements. Note in some embodiments, the display element 210 may also include some or all of the functionality of the optics block 735.

The optics block 735 may magnify image light received from the electronic display, corrects optical errors associated with the image light, and presents the corrected image light to one or both eyeboxes of the headset 705. In various embodiments, the optics block 735 includes one or more optical elements. Example optical elements included in the optics block 735 include: an aperture, a Fresnel lens, a convex lens, a concave lens, a filter, a reflecting surface, or any other suitable optical element that affects image light. Moreover, the optics block 735 may include combinations of different optical elements. In some embodiments, one or more of the optical elements in the optics block 735 may have one or more coatings, such as partially reflective or anti-reflective coatings.

Magnification and focusing of the image light by the optics block 735 allows the electronic display to be physically smaller, weigh less, and consume less power than larger displays. Additionally, magnification may increase the field of view of the content presented by the electronic display. For example, the field of view of the displayed content is such that the displayed content is presented using almost all (e.g., approximately 110 degrees diagonal), and in some cases, all of the user's field of view. Additionally, in some embodiments, the amount of magnification may be adjusted by adding or removing optical elements.

In some embodiments, the optics block 735 may be designed to correct one or more types of optical error. Examples of optical error include barrel or pincushion distortion, longitudinal chromatic aberrations, or transverse chromatic aberrations. Other types of optical errors may further include spherical aberrations, chromatic aberrations, or errors due to the lens field curvature, astigmatisms, or any other type of optical error. In some embodiments, content provided to the electronic display for display is pre-distorted, and the optics block 735 corrects the distortion when it receives image light from the electronic display generated based on the content.

The position sensor 740 is an electronic device that generates data indicating a position of the headset 705. The position sensor 740 generates one or more measurement signals in response to motion of the headset 705. The position sensor 190 is an embodiment of the position sensor 740. Examples of a position sensor 740 include: one or more IMUs, one or more accelerometers, one or more gyroscopes, one or more magnetometers, another suitable type of sensor that detects motion, or some combination thereof. The position sensor 740 may include multiple accelerometers to measure translational motion (forward/back, up/down, left/right) and multiple gyroscopes to measure rotational motion (e.g., pitch, yaw, roll). In some embodiments, an IMU rapidly samples the measurement signals and calculates the estimated position of the headset 705 from the sampled data. For example, the IMU integrates the measurement signals received from the accelerometers over time to estimate a velocity vector and integrates the velocity vector over time to determine an estimated position of a reference point on the headset 705. The reference point is a point that may be used to describe the position of the headset 705. While the reference point may generally be defined as a point in space, however, in practice the reference point is defined as a point within the headset 705.

The DCA 745 generates depth information for a portion of the local area. The DCA includes one or more imaging devices and a DCA controller. The DCA 745 includes a projector that comprises a VCSEL array. The VCSEL array is a bottom emitting VCSEL array formed with the array of VCSELs. The array of VCSELs is coupled with a substrate. The substrate includes an optical layer formed from a portion of the substrate, and the optical layer includes a plurality of optical features. The light emitted from the VCSELs passes through the optical features to generate one or more SL patterns. Thus, optical features are a wafer level optics that is integrated into and/or function as the projector. The projector does not need a collimator and directly generates SL patterns. In some embodiments, the projector may further include a collimator to modify the emitted light. The VCSELs are grouped into one or more regions, and each region may be controlled independently. The substrate may include a plurality of WLO prisms. The emitted light from the VCSELs in each region passes through the collimator and is projected to a designated region of interest. By switching on the VCSELs from one region to another, the projector may scan a full field of view from one region of interest to another. In some embodiments, the substrate is a micro lens layer which includes a plurality of micro lenses. The micro lenses are oriented with a certain angle relative their helical axes so that the plurality of micro lenses are wafer level optics that function as a collimator. The light emitted from the VCSEL array may be collimated by the micro lenses and projected as flood light in a local area. Operation and structure of the DCA 745 is described above with regard to FIG. 1.

The audio system 750 provides audio content to a user of the headset 705. The audio system 750 may comprise one or acoustic sensors, one or more transducers, and an audio controller. The audio system 750 may provide spatialized audio content to the user. In some embodiments, the audio system 750 may request acoustic parameters from a server over a network 720. The acoustic parameters describe one or more acoustic properties (e.g., room impulse response, a reverberation time, a reverberation level, etc.) of the local area. The audio system 750 may provide information describing at least a portion of the local area from e.g., the DCA 745 and/or location information for the headset 705 from the position sensor 740. The audio system 750 may generate one or more sound filters using one or more of the acoustic parameters received from the server, and use the sound filters to provide audio content to the user.

The I/O interface 710 is a device that allows a user to send action requests and receive responses from the console 715. An action request is a request to perform a particular action. For example, an action request may be an instruction to start or end capture of image or video data, or an instruction to perform a particular action within an application. The I/O interface 710 may include one or more input devices. Example input devices include: a keyboard, a mouse, a game controller, or any other suitable device for receiving action requests and communicating the action requests to the console 715. An action request received by the I/O interface 710 is communicated to the console 715, which performs an action corresponding to the action request. In some embodiments, the I/O interface 710 includes an IMU that captures calibration data indicating an estimated position of the I/O interface 710 relative to an initial position of the I/O interface 710. In some embodiments, the I/O interface 710 may provide haptic feedback to the user in accordance with instructions received from the console 715. For example, haptic feedback is provided when an action request is received, or the console 715 communicates instructions to the I/O interface 710 causing the I/O interface 710 to generate haptic feedback when the console 715 performs an action.

The console 715 provides content to the headset 705 for processing in accordance with information received from one or more of: the DCA 745, the headset 705, and the I/O interface 710. In the example shown in FIG. 7, the console 715 includes an application store 655, a tracking module 760, and an engine 765. Some embodiments of the console 715 have different modules or components than those described in conjunction with FIG. 7. Similarly, the functions further described below may be distributed among components of the console 715 in a different manner than described in conjunction with FIG. 7. In some embodiments, the functionality discussed herein with respect to the console 715 may be implemented in the headset 705, or a remote system.

The application store 655 stores one or more applications for execution by the console 715. An application is a group of instructions, that when executed by a processor, generates content for presentation to the user. Content generated by an application may be in response to inputs received from the user via movement of the headset 705 or the I/O interface 710. Examples of applications include: gaming applications, conferencing applications, video playback applications, or other suitable applications.

The tracking module 760 tracks movements of the headset 705 or of the I/O interface 710 using information from the DCA 745, the one or more position sensors 740, or some combination thereof. For example, the tracking module 760 determines a position of a reference point of the headset 705 in a mapping of a local area based on information from the headset 705. The tracking module 760 may also determine positions of an object or virtual object. Additionally, in some embodiments, the tracking module 760 may use portions of data indicating a position of the headset 705 from the position sensor 740 as well as representations of the local area from the DCA 745 to predict a future location of the headset 705. The tracking module 760 provides the estimated or predicted future position of the headset 705 or the I/O interface 710 to the engine 765.

The engine 765 executes applications and receives position information, acceleration information, velocity information, predicted future positions, or some combination thereof, of the headset 705 from the tracking module 760. Based on the received information, the engine 765 determines content to provide to the headset 705 for presentation to the user. For example, if the received information indicates that the user has looked to the left, the engine 765 generates content for the headset 705 that mirrors the user's movement in a virtual local area or in a local area augmenting the local area with additional content. Additionally, the engine 765 performs an action within an application executing on the console 715 in response to an action request received from the I/O interface 710 and provides feedback to the user that the action was performed. The provided feedback may be visual or audible feedback via the headset 705 or haptic feedback via the I/O interface 710.

The network 720 may couples the headset 705 and/or the console 715 to each other and/or one or more servers. The network 720 may include any combination of local area and/or wide area networks using both wireless and/or wired communication systems. For example, the network 720 may include the Internet, as well as mobile telephone networks. In one embodiment, the network 720 uses standard communications technologies and/or protocols. Hence, the network 720 may include links using technologies such as Ethernet, 802.11, worldwide interoperability for microwave access (WiMAX), 2G/3G/4G mobile communications protocols, digital subscriber line (DSL), asynchronous transfer mode (ATM), InfiniBand, PCI Express Advanced Switching, etc. Similarly, the networking protocols used on the network 720 can include multiprotocol label switching (MPLS), the transmission control protocol/Internet protocol (TCP/IP), the User Datagram Protocol (UDP), the hypertext transport protocol (HTTP), the simple mail transfer protocol (SMTP), the file transfer protocol (FTP), etc. The data exchanged over the network 720 can be represented using technologies and/or formats including image data in binary form (e.g., Portable Network Graphics (PNG)), hypertext markup language (HTML), extensible markup language (XML), etc. In addition, all or some of links can be encrypted using conventional encryption technologies such as secure sockets layer (SSL), transport layer security (TLS), virtual private networks (VPNs), Internet Protocol security (IPsec), etc.

One or more components of system 700 may contain a privacy module that stores one or more privacy settings for user data elements. The user data elements describe the user or the headset 705. For example, the user data elements may describe a physical characteristic of the user, an action performed by the user, a location of the user of the headset 705, a location of the headset 705, an HRTF for the user, etc. Privacy settings (or “access settings”) for a user data element may be stored in any suitable manner, such as, for example, in association with the user data element, in an index on an authorization server, in another suitable manner, or any suitable combination thereof.

A privacy setting for a user data element specifies how the user data element (or particular information associated with the user data element) can be accessed, stored, or otherwise used (e.g., viewed, shared, modified, copied, executed, surfaced, or identified). In some embodiments, the privacy settings for a user data element may specify a “blocked list” of entities that may not access certain information associated with the user data element. The privacy settings associated with the user data element may specify any suitable granularity of permitted access or denial of access. For example, some entities may have permission to see that a specific user data element exists, some entities may have permission to view the content of the specific user data element, and some entities may have permission to modify the specific user data element. The privacy settings may allow the user to allow other entities to access or store user data elements for a finite period of time.

The privacy settings may allow a user to specify one or more geographic locations from which user data elements can be accessed. Access or denial of access to the user data elements may depend on the geographic location of an entity who is attempting to access the user data elements. For example, the user may allow access to a user data element and specify that the user data element is accessible to an entity only while the user is in a particular location. If the user leaves the particular location, the user data element may no longer be accessible to the entity. As another example, the user may specify that a user data element is accessible only to entities within a threshold distance from the user, such as another user of a headset within the same local area as the user. If the user subsequently changes location, the entity with access to the user data element may lose access, while a new group of entities may gain access as they come within the threshold distance of the user.

The system 700 may include one or more authorization/privacy servers for enforcing privacy settings. A request from an entity for a particular user data element may identify the entity associated with the request and the user data element may be sent only to the entity if the authorization server determines that the entity is authorized to access the user data element based on the privacy settings associated with the user data element. If the requesting entity is not authorized to access the user data element, the authorization server may prevent the requested user data element from being retrieved or may prevent the requested user data element from being sent to the entity. Although this disclosure describes enforcing privacy settings in a particular manner, this disclosure contemplates enforcing privacy settings in any suitable manner.

### Additional Configuration Information

The foregoing description of the embodiments of the disclosure has been presented for the purpose of illustration; it is not intended to be exhaustive or to limit the disclosure to the precise forms disclosed. Persons skilled in the relevant art can appreciate that many modifications and variations are possible in light of the above disclosure.

Some portions of this description describe the embodiments of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments of the disclosure may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the disclosure may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the disclosure, which is set forth in the following claims.

What is claimed is:

1. A projector comprising:
a vertical cavity surface emitting laser (VCSEL) array, including a bottom emitting VCSEL, wherein the bottom emitting VCSEL emits light through a substrate and the substrate includes a plurality of optical features to generate one or more structured light (SL) patterns from the emitted light.

2. The projector of claim 1, wherein the one or more SL patterns include a quasi-sinusoidal bar pattern.

3. The projector of claim 1, wherein the optical features form a one-dimensional grating.

4. The projector of claim 1, wherein the optical features form a two-dimensional grating.

5. The projector of claim 1, wherein the VCSEL array includes a plurality of bottom emitting VCSELs, and the plurality of bottom emitting VCSELs are positioned in a plurality of columns.

6. The projector of claim 1, wherein the optical features are formed in groups, and different groups of the optical features are configured to generate the structured light patterns that are diffracted at different angles.

7. The projector of claim 1, further comprising a prism coupled to the substrate, the prism increasing a projected field of view of a SL pattern of the one or more SL patterns.

8. The projector of claim 7, wherein the plurality of optical features are within an area of the substrate, and the prism is positioned along a periphery of the area.

9. The projector of claim 8, further comprising a second prism that is positioned along the periphery of the area.

10. The projector of claim 1, further comprising an optical layer formed on the substrate, wherein the optical layer modifies the one or more SL patterns.

11. The projector of claim 10, wherein the optical layer includes a second plurality of optical features.

12. The projector of claim 1, wherein the substrate is composed of a material that is transparent to the emitted light from the VCSEL array.

13. The projector of claim 12, wherein the substrate is composed of GaAs.

14. The projector of claim 1, wherein the projector does not include a collimating optical element.

15. The projector of claim 1, wherein the bottom emitting VCSEL includes:
a first reflective layer that is formed on the substrate;
a second reflective layer that is electrically coupled to a base; and
an active layer between the first reflective layer and the second reflective layer.

16. The projector of claim 1, wherein the projector is part of a depth camera assembly (DCA).

17. The projector of claim 16, wherein the DCA is integrated into a headset.

18. A depth camera assembly comprising:
a VCSEL array, including a bottom emitting VCSEL, wherein the bottom emitting VCSEL emits light through a substrate and the substrate includes a plurality of optical features to generate one or more structured light (SL) patterns from the emitted light; and
an imaging device configured to capture the structured light patterns that is reflected or scattered from a local area.

19. The depth camera assembly of claim 18, wherein the optical features form a one-dimensional grating.

20. The depth camera assembly of claim 18, further comprising a prism coupled to the substrate, the prism increasing a projected field of view of a SL pattern of the one or more SL patterns.
